(19) United States
(12) Patent Application Publication
(10) Pub. No.: US 2025/0105012 A1
(43) Pub. Date: Mar. 27, 2025

(54) METAL AND CARBON CONTAINING LAYERS, INCLUDING METHODS AND SYSTEMS FOR THEIR MANUFACTURE

(71) Applicant: ASM IP Holding B.V., Almere (NL)

(72) Inventors: Charles Dezelah, Helsinki (FI); Giueseppe Alessio Verni, Vantaa (FI); Petro Deminskyi, Espoo (FI); Balaji Kannan, Phoenix, AZ (US); Eric Jen cheng Liu, Tempe, AZ (US); Fu Tang, Gilbert, AZ (US); Michael Givens, Oud-Heverlee (BE); Eric James Shero, Phoenix, AZ (US)

(21) Appl. No.: 18/896,482

(22) Filed: Sep. 25, 2024

Related U.S. Application Data
(60) Provisional application No. 63/540,536, filed on Sep. 26, 2023.

(51) Int. Cl. H01L 21/28

(52) U.S. Cl. CPC H01L 21/28194; H01L 21/28185

(57) ABSTRACT

Aspects of the disclosure relate to the field of semiconductor devices, including methods and systems for manufacturing semiconductor devices. More particularly, semiconductor structures comprise a dipole layer, which can be formed from a metal and carbon containing layer. Further described are related methods, deposition systems, and devices.

### CROSS-REFERENCE TO RELATED APPLICATION(S)

This application claims the benefit of U.S. Provisional Application 63/540,536 filed on Sep. 26, 2023, the entire contents of which are incorporated herein by reference.

### FIELD OF INVENTION

The present disclosure generally relates to the field of semiconductor devices. More particularly, semiconductor structures comprising a dipole layer. The dipole layer can be formed by means of a layer comprising a metal and carbon.

### BACKGROUND OF THE DISCLOSURE

Transistors are integrated circuit components or elements that are often formed on a semiconductor substrate. Specifically, modern integrated circuits incorporate field-effect transistors (FETs) in which current flows through a semiconducting channel between a source and a drain, in response to a voltage applied to a control gate. The scaling of semiconductor devices, such as, for example, complementary metal-oxide-semiconductor (CMOS) devices, has led to significant improvements in speed and density of modern integrated circuits. In advanced CMOS devices, including central processing unit (CPU) and system-on-a-chip (SoC), structures with multiple threshold voltages are needed in order to optimize delay or power consumption. However, as device dimensions have shrunk, providing highly functional structures with multiple threshold voltages is facing serious challenges. For instance, one particular problem is controlling the threshold voltage of FETs.

State of the art solutions employ dipole layers for controlling the threshold voltage of transistors, e.g. by means of layers comprising oxides of one or more of lanthanum, scandium, and aluminum. However, the deposition of these layers may generate an oxide such as silicon oxide at the semiconductor-gate dielectric interface, which can increase the equivalent oxide thickness (EOT) of the device which negatively affects switching speed.

State of the art methods can comprise forming thick metallic layers on top of high-k layers which are then used to tune the threshold voltage. This necessitate fairly thick layers (1-4 nm) to achieve the required effective work function shift. However, the gate cavities for emerging scaled semiconductor devices do not provide enough space to deposit thick films. Furthermore, dipole layers should be deposited in a way allowing them to penetrate through the high-k films down to the Si surface for dipole last approach, which cause additional restrictions for films thickness and thus, their properties.

Therefore, there is a need for ways to achieve better performance while scaling down integrated circuits.

### SUMMARY OF THE DISCLOSURE

In the present disclosure, carbon-containing layers are disclosed to form dipoles as a way to control the threshold voltage and the effective oxide thickness of MOS transistors to improve the electrical performance of integrated circuits. The present disclosure includes a disclosure of dipole layers comprising a carbide or carbonitride material.

Described herein is a method of forming a gate dielectric, the method comprising providing a substrate to a reaction chamber, the substrate comprising a semiconductor; executing a plurality of deposition cycles, ones from the plurality of deposition cycles comprising a metal precursor pulse that comprises introducing a metal precursor to the reaction chamber, thereby contacting the substrate with the metal precursor; a carbon reactant pulse that comprises introducing a carbon reactant to the reaction chamber, thereby contacting the substrate with the carbon reactant; thereby forming a metal and carbon containing layer on the substrate.

In some embodiments, the substrate comprises a semiconductor and at least one of an interlayer and a high-k layer, wherein the method further comprises a step of annealing the substrate, thereby forming a dipole layer.

In some embodiments, the substrate comprises an interlayer, wherein the metal and carbon containing layer is formed on the interlayer, wherein the method further comprises forming a high-k layer on the metal and carbon containing layer, and wherein the method further comprises a step of annealing, thereby forming a dipole layer.

In some embodiments, the metal and carbon containing layer is formed on the high-k layer.

In some embodiments, the metal precursor comprises a rare earth metal.

In some embodiments, the rare earth metal is selected from scandium (Sc), yttrium (Y), lanthanum (La), and erbium (Er).

In some embodiments, the metal precursor comprises a transition metal.

In some embodiments, the transition metal is selected from the list consisting of Ti, Zr, Hf, V, Nb, Ta, Cr, Mo, W, and Mn.

In some embodiments, the metal precursor comprises a cyclopentadienyl ligand.

In some embodiments, the metal precursor comprises an amidinate ligand.

In some embodiments, the metal precursor comprises an alkylsilazido ligand.

In some embodiments, the metal precursor comprises an dialkylamido ligand.

In some embodiments, the metal precursor comprises a metal halide.

In some embodiments, the metal precursor comprises an arene or alkylarene ligand

In some embodiments, ones from the plurality of deposition cycles further comprise a nitrogen reactant pulse that comprises introducing a nitrogen reactant to the reaction chamber, thereby contacting the substrate with the nitrogen reactant.

In some embodiments, the nitrogen reactant is selected from ammonia, hydrazine, and a hydrazine derivative.

In some embodiments, the nitrogen reactant comprises a hydrazine derivative selected from 1,1-dimethylhydrazine and tert-butylhydrazine.

In some embodiments, the carbon reactant comprises a cyclodiene.

In some embodiments, the cyclodiene is selected from 1,3-cyclohexadiene and 1,4-cyclohexadiene.

In some embodiments, the cyclodiene comprises one or more alkyl or alkylsilyl substituents.

In some embodiments, the cyclodiene is selected from 3,6-bis(trimethylsilyl)-1,4-cyclohexadiene and 1-Methyl-3,6-bis(trimethylsilyl)-1,4-cyclohexadiene.

In some embodiments, the cyclodiene comprises one or more of cyclopentadiene and dicyclopentadiene.

In some embodiments, the carbon reactant comprises a diiodoalkane.

In some embodiments, the diiodoalkane is selected from diiodomethane, 1,2-diiodoethane, and 1,3-diiodopropane.

In some embodiments, the carbon reactant comprises one or more of allyl halide, propargyl halide, and benzyl halide.

In some embodiments, the carbon reactant comprises a triple carbon-carbon bond.

In some embodiments, the carbon reactant is selected from acetylene and bis(trimethylsilyl) acetylene.

In some embodiments, the carbon reactant comprises one or more of a cyclopropane and a cyclopropyl group.

In some embodiments, the carbon reactant comprises a metal alkyl.

In some embodiments, the metal alkyl is selected from trimethylaluminum, triethylaluminum, and diethylzinc.

In some embodiments, the carbon reactant comprises a boron alkyl.

In some embodiments, the boron alkyl comprises triethylboron.

In some embodiments, each pulse is followed by a purge with a purge gas.

In some embodiments, the purge gas comprises one or more of N₂ and a noble gas.

In some embodiments, the dipole layer has an average thickness of 1 nm or less.

In some embodiments, executing the plurality of deposition cycles does not comprise contacting the substrate with an oxygen reactant.

In some embodiments, the substrate comprises silicon or silicon oxide.

In some embodiments, the metal and carbon containing layer comprises a transition metal carbide; wherein the metal precursor comprises a transition metal precursor selected from the list consisting of: M(NtBu)₂(NMe₂)₂, M₂(NMe₂)₆, M(arene)₂, MF₆, MCl₆, MCl₅, MCp₂H₂, MCp₂Cl₂, M(iPrCp)₂H₂, and M(iPrCp)₂Cl₂, with M being a transition metal.

In some embodiments, the metal and carbon containing layer comprises a transition metal oxycarbide; wherein the metal comprises a transition metal precursor selected from the list consisting of M(acac)₃, M(thd)₃, MO₂(tBuAMD)₂, MO₂Cl₂, MOCl₄, MFxOy with x and y being independently selected integers from at least 1 to 6 with x+2y being equal to 6, M(CO)₆, MO₂(thd)₂, MO₂(acac)₂, M(arene)(CO)₃, M₂(OR)₆ with R selected from Me, Et, and iPr. and with M being a transition metal.

In some embodiments, the carbon reactant is selected from the list consisting of AlMe₃, propargyl halides selected from chlorides borides and iodides, allyl halides selected from chlorides, bromides, and iodides, HCp, cyclohexadiene, and AlH₂(tBuNCH₂CH₂NMe₂).

In some embodiments, the metal and carbon containing layer comprises a transition metal carbonitride. In such embodiments, the transition metal precursor can be selected from M(NtBu)₂(NMe₂)₂, M₂(NMe₂)₆, MF₆, MCl₆, MCl₅, and a transition metal triazenide, with M being a transition metal.

In some embodiments, the carbon reactant is selected from the list consisting of hydrazine and tertbutyl hydrazine.

In some embodiments, the transition metal is selected from the group consisting of W, Ti, V, Cr, Mn, Zr, Nb, Mo, Hf, and Ta.

Further described herein is a system comprising a reaction chamber and a controller, the system being constructed and arranged for carrying out a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates an embodiment of a method 100 that can be used to, for example, forming a metal and carbon containing layer.

FIGS. 2 and 3 show flow-charts of embodiments of methods of forming a gate stack for a transistor.

FIG. 4 illustrates an exemplary structure in accordance with examples of the disclosure.

FIG. 5 illustrates a system in accordance with exemplary embodiments of the disclosure

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes are not necessarily comprised of a sequence of self-limiting surface reactions.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The following abbreviations are used herein: Ti stands for titanium, Zr stands for zirconium, Hf stands for hafnium, V stands for vanadium, Nb stands for niobium, Ta stands for tantalum, Cr stands for chromium, Mo stands for molybdenum, W stands for tungsten, Mn stands for manganese, Me stands for methyl, Et stands for ethyl, iPr stands for isopropyl, nPr stands for n-propyl, nBu stands for n-butyl, tBu stands for tert-butyl, N stands for nitrogen, P stands for phosphorous, C stands for carbon, H stands for hydrogen, F stands for fluorine, Cl stands for chlorine, Cp stands for cyclopentadienyl, acac stands for acetylacetonate, tBuAMD stands for N,N′-di-tert-butylacetamidinate, thd stands for 2-[3-[(4-amino-2-methyl-5-pyrimidinyl)methyl]-2-(1,2-dihydroxyethyl)-4-methyl-1,3-thiazol-3-ium-5-yl]ethyl trihydrogen diphosphate.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

The presently described methods and devices are useful for controlling the threshold voltage of field effect transistors. In some embodiments, the present methods and devices are particularly useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In particular, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices are particularly useful for decreasing the gate voltage at which a conductive channel is produced between the source and drain of a p-MOSFET. The p-MOSFET may, for example, be comprised in a CMOS-based integrated circuit. In other words, the present methods and devices are particularly useful for increasing the voltage at which an n-MOSFET switches from an off-state to an on-state, and for decreasing the voltage at which a p-MOSFET switches from an off-state to an on-state. Similarly, the present methods and devices are particularly useful for increasing the flat band voltage of n-MOSFETS, and for decreasing the flat band voltage of p-MOSFETS. The presently methods and devices are particularly useful for the manufacture of n-MOSFETS and p-MOSFETS with a gate-all-around architecture. Additionally or alternatively, the present methods and devices may be of particular use in the context of systems-on-a-chip. Advantageously, the presently disclosed methods allow depositing threshold shifting layers contributing only minimally to the equivalent oxide thickness of the gate dielectric stack while simultaneously offering a low growth rate and providing a significant positive threshold voltage shift. Advantageously, the presently disclosed methods allow depositing threshold shifting layers having a low impurity content.

Described herein are methods of forming dipole layers, and methods that can be useful in the context of manufacturing dipole layers. In particular, described herein is an embodiment of a method that can comprise providing a substrate to a reaction chamber. In some embodiments, the substrate comprises a semiconductor. The method can further comprise executing a plurality of deposition cycles. Ones from the plurality of deposition cycles can comprise a metal precursor pulse and a carbon reactant pulse. The metal precursor pulse comprises introducing a metal precursor to the reaction chamber. Thus, the substrate can be contacted with the metal precursor. The carbon reactant pulse comprises introducing a carbon reactant to the reaction chamber. Thus, the substrate can be contacted with the carbon reactant. By executing the plurality of deposition cycles, a metal and carbon containing layer can be formed on the substrate. Advantageously, the produced layer functions as, or can be employed to form, a dipole layer and enables tuning of the effective work function of a gate without producing an interfacial metal oxide that has an EOT penalty.

In some embodiments, the metal and carbon containing layer can be formed by means of one or more processes, precursors, and reactants described in U.S. patent application Ser. No. 17/546,186, publication number US2022189775A1, which is incorporated herein by reference in its entirety.

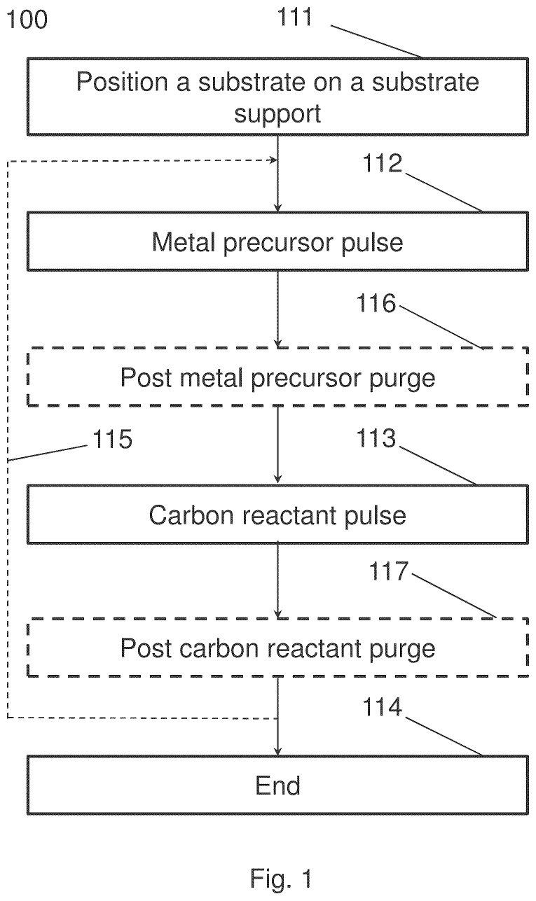

An embodiment of a method according to the present disclosure is described with reference to FIG. 1. FIG. 1 particularly illustrates an embodiment of a method 100 that can be used to, for example, form a metal and carbon containing layer that can be employed as, or forming a, dipole layer for transistors such as NMOS, PMOS, and/or CMOS devices. Suitable transistors include gate all around transistors, nanosheet devices, fork sheet devices, vertical field effect transistors, stacked device architectures, etc.

The method 100 includes a step 111 of providing a substrate within a reaction chamber of a reactor. The reaction chamber can be or include a reaction chamber of a chemical vapor deposition reactor system configured to perform a cyclical deposition process. Additionally or alternatively, the reaction chamber can be or can include a reaction chamber of an atomic layer deposition reactor system configured to perform a cyclical deposition process. The reaction chamber can be a standalone reaction chamber or part of a cluster tool.

The method further includes using a cyclical deposition process, depositing a threshold voltage shifting layer as described herein, onto a surface of the substrate. The substrate comprises a silicon oxide surface and/or a high-k dielectric surface. Then, the method comprises cyclically executing one or more cycles 115, e.g. a plurality of cycles, e.g. 2, 5, 10, or 20, 50, 100, 200, 500, 1000, or more cycles. A cycle can comprise the following steps, in the following order: a metal precursor pulse 112, and a carbon reactant pulse 113. Alternatively, a cycle can comprise the following steps, in the following order: a carbon reactant pulse, and a metal precursor pulse. Thus, a metal and carbon containing layer can be deposited on the substrate, and the method ends.

Optionally, the metal precursor pulse and the carbon reactant pulse can be separated by an intra-cycle purge 116. Additionally or alternatively, subsequent cycles can, in some embodiments, be separated by an inter-cycle purge 117.

The method according to FIG. 1 can include cyclically executing a plurality of deposition cycles 115. A deposition cycle comprises the metal precursor pulse 112, and the carbon reactant pulse 113. Optionally, a deposition cycle comprises an intra-cycle purge 116 and/or an inter-cycle purge 117. The deposition cycle can be repeated one or more times, based on, for example, a desired thickness of the threshold voltage shifting layer. For example, if the thickness of the threshold voltage shifting layer is less than desired for a particular application, then the step of providing a precursor to the reaction chamber and providing a reactant to the reaction chamber can be repeated one or more times. Once the threshold voltage shifting layer has been deposited to a desired thickness, the substrate can be subjected to additional processes to form a device structure and/or device.

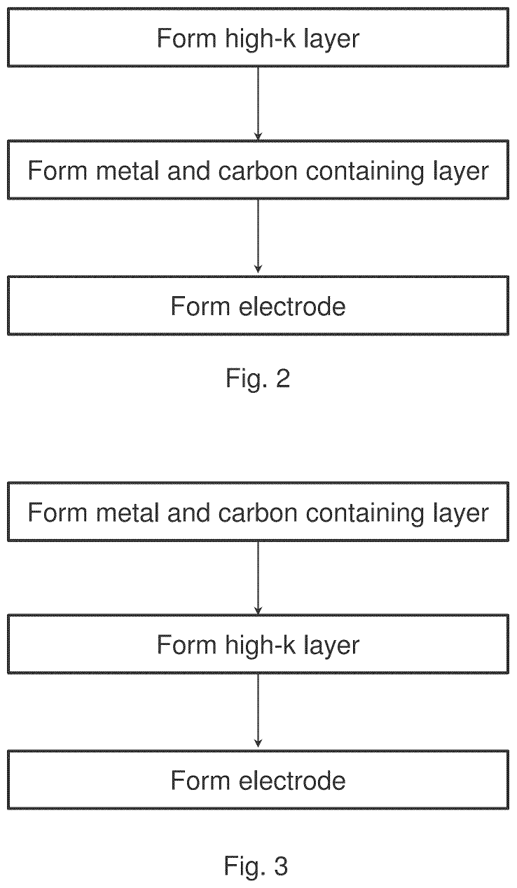

In some embodiments, metal and carbon containing layer as described herein can be particularly advantageously formed on a high-k dielectric, i.e. the metal and carbon containing layer can be formed after formation of a high-k dielectric such as hafnium oxide. In other words, a method as described herein can comprise first forming a high-k dielectric, and then forming a metal and carbon-containing layer. Such a dipole last configuration can be useful in older or less scaled process nodes because it can be more resistant to certain contaminants. Such an embodiment is illustrated by means of FIG. 2 which shows a flow-chart of an embodiment of a method of forming a gate stack for a transistor. The method can comprise first forming a high-k layer, then forming a metal and carbon-containing layer on the high-k layer, and subsequently forming an electrode on the high-k layer. The high-k layer can be deposited overlying an interface layer. In some cases, the interface layer may not exist or may not exist to an appreciable extent. The interface layer can include an oxide, such as a silicon oxide, which can for example be formed on a, for example monocrystalline silicon, surface of the substrate using, for example, a chemical oxidation process or an oxide deposition process. The high-k material can be or include, for example, a metal oxide having a dielectric constant greater than about 7. In some embodiments, the high-k material has a dielectric constant higher than the dielectric constant of silicon oxide. Exemplary high-k materials include hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃) or lanthanum oxide (La₂O₃), mixtures thereof, and laminates thereof.

In some embodiments, metal and carbon containing layer as described herein can be particularly advantageously formed on an interfacial layer, e.g. a silicon oxide layer, i.e. prior to formation of a high-k dielectric such as hafnium oxide. In other words, a method as described herein can comprise first forming a metal and carbon containing layer, and then forming a high-k dielectric. Such a dipole first configuration is highly advantageous in advanced process nodes since it can require a lower thermal budget to form the dipole layer—the metal does not have to penetrate the high-k layer to form a dipole at the semiconductor—dielectric interface. Such an embodiment is illustrated by means of FIG. 3 which shows a flow-chart of another embodiment of a method of forming a gate stack for a transistor. It is similar to the method illustrated by means of FIG. 2, except that the metal and carbon containing layer is formed between the interface layer and the high-k material, i.e. the metal and carbon containing layer is formed before the high-k layer is formed.

For example, the substrate can be annealed to form a dipole layer by means of the metal and carbon containing layer. Thus, in some embodiments, the substrate comprises a semiconductor and at least one of an interlayer and a high-k layer, wherein the method further comprises a step of annealing the substrate, thereby forming a dipole layer.

In some embodiments, the substrate is subjected to an anneal after the cyclical deposition process has been carried out, e.g. after both the metal and carbon containing layer and a high-k layer have been formed. In some embodiments after a metallic layer has been formed on the high-k layer or on the metal and carbon containing layer. The anneal can be carried out, for example, in an ambient comprising hydrogen and nitrogen. The anneal can be carried out, for example, at a temperature of at least 300° C. to at most 600° C., or at a temperature of at least 300° C. to at most 400° C., or at a temperature of at least 400° C. to at most 500° C., or at a temperature of at least 500° C. to at most 600° C. The anneal can be carried out for example, for from at least 5 minutes to at most 40 minutes, for example from at least 10 minutes to at most 30 minutes. In an exemplary embodiment, the anneal is carried out at from at least 400° C. to at most 500° C., e.g. at 420° C., for from at least 10 minutes to at most 30 minutes, e.g. for 20 minutes, in forming gas, i.e. H₂ in N₂. In exemplary embodiments, the forming gas can comprise from at least 1 atomic percent to at most 20 atomic percent H₂ in N₂, for example about 5 atomic percent H₂ in N₂.

In some embodiments, the precursor is provided to the reactor chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature controlled precursor vessel is maintained at a temperature of at least-50° C. to at most 20° C., or at a temperature of at least 20° C. to at most 250° C., or at a temperature of at least 100° C. to at most 200° C.

In some embodiments, the precursor is provided to the reactor chamber by means of a carrier gas. Exemplary carrier gasses include nitrogen and a noble gas such as He, Ne, Ar, Xe, or Kr.

In some embodiments, the precursor pulses last from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the reactant pulses last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, the substrate comprises an interlayer. The metal and carbon containing layer can be formed on the interlayer. The method can further comprise forming a high-k layer on the metal and carbon containing layer. The method can further comprise a step of annealing the substrate. Thus, a dipole layer is formed.

In some embodiments, metal and carbon containing layer is formed on the high-k layer.

In some embodiments, the anneal can be carried out after the high-k layer is formed.

In some embodiments, the anneal can be carried out after a conductive layer has been formed on the high-k layer.

The anneal can be carried out, for example, in an ambient comprising hydrogen and nitrogen. The anneal can be carried out, for example, at a temperature of at least 300° C. to at most 600° C., or at a temperature of at least 300° C. to at most 400° C., or at a temperature of at least 400° C. to at most 500° C., or at a temperature of at least 500° C. to at most 600° C. The anneal can be carried out for example, for from at least 5 minutes to at most 40 minutes, for example from at least 10 minutes to at most 30 minutes. In an exemplary embodiment, the anneal is carried out at from at least 400° C. to at most 500° C., e.g. at 420° C., for from at least 10 minutes to at most 30 minutes, e.g. for 20 minutes, in forming gas, i.e. H₂ in N₂. In exemplary embodiments, the forming gas can comprise from at least 1 atomic percent to at most 20 atomic percent H₂ in N₂, for example about 5 atomic percent H₂ in N₂.

Suitable conductive layers include transition metal containing layers such as transition metal nitrides such as titanium nitride, post transition metal containing layers such as post transition metal carbides such as aluminum carbide, and rare earth element-containing layers such as rare earth element carbides such as cerium carbide.

In some embodiments, the metal precursor comprises a rare earth metal.

In some embodiments, the rare earth metal is selected from scandium (Sc), yttrium (Y), lanthanum (La), and erbium (Er).

In some embodiments, the metal precursor comprises a transition metal.

In some embodiments, the transition metal is selected from the list consisting of Ti, Zr, Hf, V, Nb, Ta, Cr, Mo, W, and Mn.

In some embodiments, the metal precursor comprises a cyclopentadienyl ligand.

In some embodiments, the metal precursor comprises an amidinate ligand.

In some embodiments, the metal precursor comprises an alkylsilazido ligand such as a hexamethyldisilazido ligand.

In some embodiments, the metal precursor comprises an dialkylamido ligand such as a dimethylamido ligand.

In some embodiments, the metal precursor comprises a metal halide such as a metal chloride.

In some embodiments, the metal precursor comprises an arene or alkylarene ligand such as a methylbenzene ligand.

In some embodiments, ones from the plurality of deposition cycles further comprise a nitrogen reactant pulse that comprises introducing a nitrogen reactant to the reaction chamber, thereby contacting the substrate with the nitrogen reactant. Thus, the metal and carbon containing layer can comprise a metal carbonitride.

In some embodiments, the nitrogen reactant is selected from ammonia, hydrazine, and a hydrazine derivative. Suitable hydrazine derivatives include compounds selected from 1,1-dimethylhydrazine and tert-butylhydrazine.

In some embodiments, the carbon reactant comprises a cyclodiene. Suitable cyclodienes can include compounds selected from 1,3-cyclohexadiene and 1,4-cyclohexadiene. In some embodiments, the cyclodiene comprises one or more alkyl or alkylsilyl substituents. In some embodiments, the cyclodiene is selected from 3,6-bis(trimethylsilyl)-1,4-cyclohexadiene and 1-Methyl-3,6-bis(trimethylsilyl)-1,4-cyclohexadiene. In some embodiments, the cyclodiene comprises one or more of cyclopentadiene and dicyclopentadiene.

In some embodiments, the carbon reactant comprises a halogen such as chlorine, bromine, and iodine.

In some embodiments, the carbon reactant comprises a haloalkane such as a iodoalkane such as a diiodoalkane. Suitable iodoalkanes, e.g. diiodoalkanes, include those in which the chlorine substituents are bonded to one or more terminal carbons. For example, a diiodoalkane can comprise a C2 to C6 linear alkane in which the terminal carbons are each bonded to one iodine atom. In some embodiments, the diiodoalkane is selected from diiodomethane, 1,2-diiodoethane, and 1,3-diiodopropane.

In some embodiments, the carbon reactant comprises one or more unsaturated carbon-carbon bonds. In some embodiments, the carbon reactant comprises one or more carbon-carbon double bonds. In some embodiments, the carbon reactant comprises one or more carbon-carbon triple bonds. In some embodiments, the carbon reactant comprises an aromatic ring. In some embodiments, the carbon reactant is selected from one or more of allyl halide, propargyl halide, and benzyl halide. In some embodiments, the carbon reactant is selected from acetylene and bis(trimethylsilyl) acetylene.

In some embodiments, the carbon reactant comprises one or more of cyclopropane and a cyclopropyl group.

In some embodiments, the carbon reactant comprises a metal alkyl.

In some embodiments, the metal alkyl is selected from trimethylaluminum, triethylaluminum, and diethylzinc.

In some embodiments, the carbon reactant comprises a boron alkyl.

In some embodiments, the boron alkyl comprises triethylboron.

In some embodiments, the metal and carbon containing layer comprises a transition metal. Suitable transition metals include W, Ti, V, Cr, Mn, Zr, Nb, Mo, Hf, and Ta. In some embodiments, the metal and carbon containing layer comprises one or more of a transition metal carbide and a transition metal nitride. In some embodiments, the metal and carbon containing layer comprises one or more of tungsten carbide and tungsten carbonitride. In some embodiments, the metal and carbon containing layer comprises a transition metal oxynitride. In some embodiments, the metal and carbon containing layer comprises tungsten oxynitride.

In some embodiments, metal precursor comprises a transition metal precursor selected from the list consisting of: M(NtBu)₂(NMe₂)₂, M₂(NMe₂)₆, M(arene)₂, MF₆, MCl₆, MCl₅, MCp₂H₂, MCp₂Cl₂, M(iPrCp)₂H₂, and M(iPrCp)₂Cl₂, with M being a transition metal. Thus, the metal precursor can comprise a transition metal alkylamine such as M(NtBu)₂(NMe₂)₂ or M₂(NMe₂)₆. Additionally or alternatively, the metal precursor can comprise a transition metal pi complex such as M(arene)₂, MCP₂H₂, MCp₂Cl₂, M(iPrCp)₂H₂ or M(iPrCp)₂Cl₂. Additionally or alternatively, the metal precursor can comprise a transition metal halide such as a transition metal chloride such as MCp₂H₂, MCp₂Cl₂, or M(iPrCp)₂Cl₂.

In some embodiments, the metal and carbon containing layer comprises a transition metal oxycarbide. In some embodiments, the metal comprises transition metal precursor selected from the list consisting of M(acac)₃, M(thd)₃, MO₂(tBuAMD)₂, MO₂Cl₂, MOCl₄, MFxOy with x and y being independently selected integers from at least 1 to 6 with x+2y being equal to 6, M(CO)₆, MO₂(thd)₂, MO₂(acac)₂, M(arene)(CO)₃, M₂(OR)₆ with R selected from Me, Et, and iPr, and with M being a transition metal. Thus, in some embodiments, the metal precursor comprises a transition metal beta-diketonate such as M(acac)₃ and M(thd)₃. In some embodiments, the metal precursor comprises a transition metal amidinate such as MO₂(tBuAMD)₂. In some embodiments, the metal precursor comprises a transition metal oxyhalide such as MO₂Cl₂, MOCl₄, MFxOy with x and y being independently selected integers from at least 1 to 6 with x+2y being equal to 6. In some embodiments, the metal precursor comprises a transition metal carbonyl such as M(CO)₆ or M(arene)(CO)₃. In some embodiments, the metal precursor comprises a transition metal pi complex such as M(arene)(CO)₃. In some embodiments, the metal precursor comprises a transition metal alkoxide such as M₂(OR)₆ with R selected from Me, Et, and iPr.

In some embodiments, the carbon reactant is selected from the list consisting of AlMe₃, propargyl halides selected from chlorides borides and iodides, allyl halides selected from chlorides, bromides, and iodides, HCp, cyclohexadiene, and AlH₂(tBuNCH₂CH₂NMe₂). Thus, in some embodiments, the carbon reactant comprises an aluminum alkyl such as AlMe₃, In some embodiments, the carbon reactant comprises a halogen bonded to an unsaturated carbon atom, such as in the case of propargyl halides selected from chlorides borides and iodides, and in the case of allyl halides selected from chlorides, bromides, and iodides. In some embodiments, the carbon reactant can comprise a cyclodiene such as cyclopentadiene or cyclohexadiene. In some embodiments, the carbon reactant comprises an amidine such as AlH₂(tBuNCH₂CH₂NMe₂).

In some embodiments, the transition metal precursor is selected from M(NtBu)₂(NMe₂)₂, M₂(NMe₂)₆, MF₆, MCl₆, MCl₅, and a transition metal triazenide, with M being a transition metal. Thus, in some embodiments, the transition metal precursor can comprise a transition metal alkylamido precursor such as M(NtBu)₂(NMe₂)₂ or M₂(NMe₂)₆. Additionally or alternatively, the transition metal precursor can comprise a halide such as a fluoride or a chloride such as one or more of MF₆, MCl₆, and MCl₅. Additionally or alternatively, the metal precursor can comprise a transition metal triazenide such as Ti(N₃tBu₂)₂(NMe₂)₂.

In some embodiments, the carbon reactant can comprise one or more of hydrazine and a hydrazine derivative such as tertbutyl hydrazine.

In some embodiments, the metal and carbon containing layer can comprise a transition metal carbide. In such embodiments, the metal precursor can comprise a transition metal precursor selected from the list consisting of: M(NtBu)₂(NMe₂)₂, M₂(NMe₂)₆, M(arene)₂, MF₆, MCl₆, MCl₅, MCp₂H₂, MCp₂Cl₂, M(iPrCp)₂H₂, and M(iPrCp)₂Cl₂, with M being a transition metal. Thus, the metal precursor can comprise a transition metal alkylamine such as M(NtBu)₂(NMe₂)₂ or M₂(NMe₂)₆. Additionally or alternatively, the metal precursor can comprise a transition metal pi complex such as M(arene)₂, MCp₂H₂, MCp₂Cl₂, M(iPrCp)₂H₂ or M(iPrCp)₂Cl₂. Additionally or alternatively, the metal precursor can comprise a transition metal halide such as a transition metal chloride such as MCp₂H₂, MCp₂Cl₂, or M(iPrCp)₂Cl₂. In such embodiments, the carbon reactant can be suitably selected from the list consisting of AlMe₃, propargyl halides selected from chlorides borides and iodides, allyl halides selected from chlorides, bromides, and iodides, HCp, cyclohexadiene, and AlH₂(tBuNCH₂CH₂NMe₂). In some embodiments, the metal and carbon containing layer comprises a transition

metal oxycarbide. In such embodiments, the metal precursor can suitably comprise a transition metal precursor selected from the list consisting of M(acac)₃, M(thd)₃, MO₂(tBuAMD)₂, MO₂Cl₂, MOCl₄, MFxOy with x and y being independently selected integers from at least 1 to 6 with x+2y being equal to 6, M(CO)₆, MO₂(thd)₂, MO₂(acac)₂, M(arene)(CO)₃, M₂(OR)₆ with R selected from Me, Et, and iPr, and with M being a transition metal. Suitable transition metals can include one or more of Scandium, Titanium, Vanadium, Chromium, Manganese, Iron, Cobalt, Nickel, Copper, Zinc, Yttrium, Zirconium, Niobium, Molybdenum, Ruthenium, Rhodium, Palladium, Silver, Cadmium, Hafnium, Tantalum, Tungsten, Rhenium, Osmium, Iridium, Platinum, Gold, and Mercury. Thus, in some embodiments, the metal precursor comprises a transition metal beta-diketonate such as M(acac)₃ and M(thd)₃. In some embodiments, the metal precursor comprises a transition metal amidinate such as MO₂(tBuAMD)₂. In some embodiments, the metal precursor comprises a transition metal oxyhalide such as MO₂Cl₂, MOCl₄, MFₓO_{y} with x and y being independently selected integers from at least 1 to 6 with x+2y being equal to 6. In some embodiments, the metal precursor comprises a transition metal carbonyl such as M(CO)₆ or M(arene)(CO)₃. In some embodiments, the metal precursor comprises a transition metal pi complex such as M(arene)(CO)₃. In some embodiments, the metal precursor comprises a transition metal alkoxide such as M₂(OR)₆ with R selected from Me, Et, and iPr. In such embodiments, the carbon reactant can be suitably selected from the list consisting of AlMe₃, propargyl halides selected from chlorides borides and iodides, allyl halides selected from allyl chlorides, allyl bromides, and allyl iodides, HCp, cyclohexadiene, and AlH₂(tBuNCH₂CH₂NMe₂).

In some embodiments, the metal and carbon containing layer comprises a transition metal carbonitride. In such embodiments, the transition metal precursor can be selected from M(NtBu)₂(NMe₂)₂, M₂(NMe₂)₆, MF₆, MCl₆, MCl₅, and a transition metal triazenide, with M being a transition metal. Thus, in some embodiments, the transition metal precursor can comprise a transition metal alkylamido precursor such as M(NtBu)₂(NMe₂)₂ or M₂(NMe₂)₆. Additionally or alternatively, the transition metal precursor can comprise a halide such as a fluoride or a chloride such as one or more of MF₆, MCl₆, and MCl₅. Additionally or alternatively, the metal precursor can comprise a transition metal triazenide such as Ti(N₃tBu₂)₂(NMe₂)₂. In such embodiments, the carbon reactant can be suitably selected from hydrazine and hydrazine derivatives such as tertbutyl hydrazine.

It shall be understood that suitable transition metals M can, in some embodiments, be selected from the group consisting of W, Ti, V, Cr, Mn, Zr, Nb, Mo, Hf, and Ta. Transition metals such as W can be advantageously employed to form dipole layers.

In some embodiments, the metal and carbon containing layer can comprise one or more of tungsten carbide, tungsten carbonitride, and tungsten oxycarbide.

A cyclical deposition process as described herein can comprise one or more purges. Purges can separate subsequent pulses by intermittently exposing the substrate to a purge gas. In some embodiments, each pulse is followed by a purge with a purge gas. Suitable purge gasses include inert or substantially inert gasses. In some embodiments, the purge gas comprises one or more of N₂ and a noble gas. Suitable noble gasses include He, Ne, Ar, Kr, and Xe.

In some embodiments, the dipole layer has an average thickness of 1 nm or less.

In some embodiments, executing the plurality of deposition cycles does not comprise contacting the substrate with an oxygen reactant such as one or more of O₂, O₃, CO₂, H₂O, N₂O, NO, or NO₂.

Further described herein is a system comprising a reaction chamber and a controller. The system can be constructed and arranged for carrying out a method as described herein.

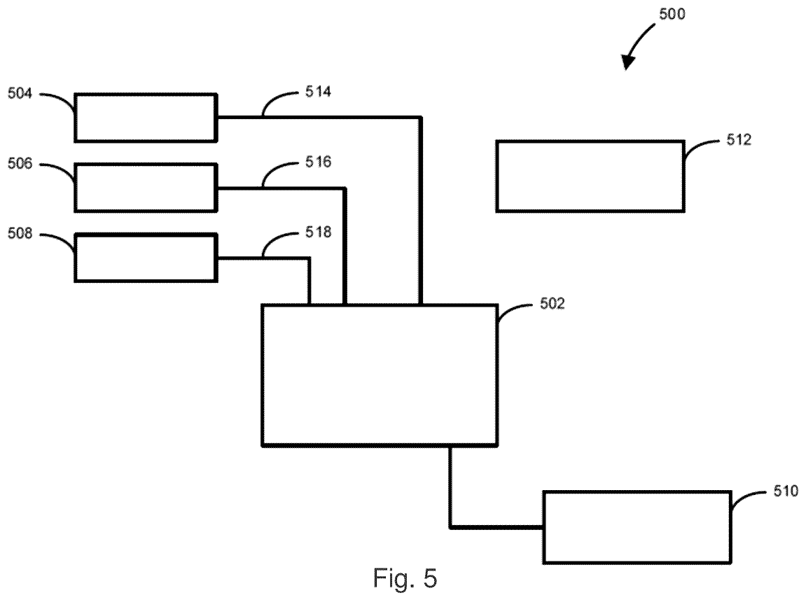

In particular, FIG. 5 illustrates a system 500 in accordance with yet additional exemplary embodiments of the disclosure. The system 500 can be used to perform a method as described herein and/or form a structure or device portion as described herein.

In the illustrated example, the system 500 includes one or more reaction chambers 502, a precursor gas source 504, a reactant gas source 506, a purge gas source 508, an exhaust source 510, and a controller 512. The reaction chamber 502 can include any suitable reaction chamber, such as an ALD or CVD reaction chamber.

The precursor gas source 504 can include a vessel and one or more precursors as described herein-alone or mixed with one or more carrier (e.g., inert) gases. The reactant gas source 506 can include a vessel and one or more reactants as described herein-alone or mixed with one or more carrier gases. The purge gas source 508 can include one or more purge gases as described herein. Although illustrated with three gas sources 504-508, the system 500 can include any suitable number of gas sources. The gas sources 504-508 can be coupled to reaction chamber 502 via lines 514-518, which can each include flow controllers, valves, heaters, and the like. The exhaust 510 can include one or more vacuum pumps.

The controller 512 includes electronic circuitry and software to selectively operate valves, manifolds, heaters, pumps and other components included in the system 500. Such circuitry and components operate to introduce precursors, reactants, and purge gases from the respective sources 504-508. The controller 512 can control timing of gas pulse sequences, temperature of the substrate and/or reaction chamber, pressure within the reaction chamber, and various other operations to provide proper operation of the system 500. The controller 512 can include control software to electrically or pneumatically control valves to control flow of precursors, reactants and purge gases into and out of the reaction chamber 502. The controller 512 can include modules such as a software or hardware component, e.g., a FPGA or ASIC, which performs certain tasks. A module can advantageously be configured to reside on the addressable storage medium of the control system and be configured to execute one or more processes.

Other configurations of the system 500 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 502. Further, as a schematic representation of a system, many components have been omitted for simplicity of illustration, and such components may include, for example, various valves, manifolds, purifiers, heaters, containers, vents, and/or bypasses.

During operation of the reactor system 500, substrates, such as semiconductor wafers (not illustrated), are transferred from, e.g., a substrate handling system to reaction chamber 502. Once substrate(s) are transferred to the reaction chamber 502, one or more gases from the gas sources 504-508, such as precursors, reactants, carrier gases, and/or purge gases, are introduced into reaction chamber 502.

Further described herein are methods of forming dipole layers, and methods that can be useful in the context of manufacturing dipole layers. In particular, described herein is an embodiment of a method that can comprise providing a substrate to a reaction chamber. In some embodiments, the substrate comprises a semiconductor. The method can further comprise executing a plurality of deposition cycles. Ones from the plurality of deposition cycles can comprise a metal precursor pulse and a nitrogen reactant pulse. The metal precursor pulse comprises introducing a metal precursor to the reaction chamber. Thus, the substrate can be contacted with the metal precursor. The nitrogen reactant pulse comprises introducing a nitrogen reactant to the reaction chamber. Thus, the substrate can be contacted with the nitrogen reactant. By executing the plurality of deposition cycles, a metal and nitrogen containing layer can be formed on the substrate. Advantageously, the produced layer functions as, or can be employed to form, a dipole layer and enables tuning of the effective work function of a gate without producing an interfacial metal oxide that has an EOT penalty. In some embodiments, the metal precursor comprises a metal precursor as described herein, such as a transition metal precursor, such as a tungsten precursor. In some embodiments, the nitrogen reactant comprises a nitrogen reactant as described herein.

In some embodiments, ones from the plurality of deposition cycles further comprise a carbon reactant pulse that comprises introducing a carbon reactant to the reaction chamber, thereby contacting the substrate with the carbon reactant. Suitable carbon reactants are described elsewhere herein.

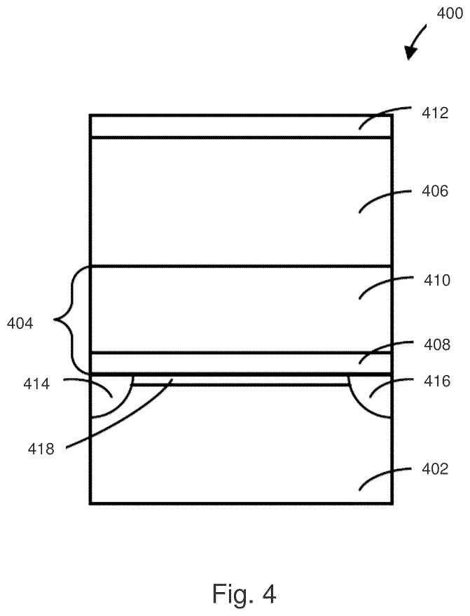

FIG. 4 illustrates an exemplary structure 400 in accordance with examples of the disclosure. The device or structure 400 includes a substrate 402, a dielectric or insulating material 404, and a dipole layer 406. The dipole layer 406 can, for example, be formed by first forming a metal and carbon containing layer on a substrate according to an embodiment of a method according to the present disclosure, and then annealing the substrate. The anneal can be done as a separate process step, or it can occur as part of the thermal budget during a subsequent process step, such as a conductive layer deposition.

The dielectric or insulating material comprises an interfacial layer 408 and a high-k dielectric layer 410. A suitable interfacial layer includes silicon oxide. In the illustrated example, the structure 400 also includes an additional conducting layer 412. In the illustrated example, the dipole layer 406 is present on top of the high-k dielectric layer 410. Alternatively, the dipole layer 406 may be present on top of the interfacial layer 408, and the high-k dielectric layer 410 may be present on the dipole layer 406.

In the illustrated example, the substrate 402 includes a source region 414, a drain region 416, and a channel region 418. Although illustrated as a horizontal structure, structures and devices in accordance with examples of the disclosure can include vertical and/or three-dimensional structures and devices, such as FinFET devices, gate-all-around field effect transistors, and stacked device architectures.

1. A method of forming a gate dielectric, the method comprising:
providing a substrate to a reaction chamber, the substrate comprising a semiconductor; and
executing a plurality of deposition cycles, ones from the plurality of deposition cycles comprising
a metal precursor pulse that comprises introducing a metal precursor to the reaction chamber, thereby contacting the substrate with the metal precursor; and
a carbon reactant pulse that comprises introducing a carbon reactant to the reaction chamber, thereby contacting the substrate with the carbon reactant,
wherein a metal and carbon containing layer is formed on the substrate.

2. The method according to claim 1, wherein the substrate comprises a semiconductor and at least one of an interlayer and a high-k layer, wherein the method further comprises a step of annealing the substrate, thereby forming a dipole layer.

3. The method according to claim 1, wherein the substrate comprises an interlayer, wherein the metal and carbon containing layer is formed on the interlayer, wherein the method further comprises forming a high-k layer on the metal and carbon containing layer, and wherein the method further comprises a step of annealing, thereby forming a dipole layer.

4. The method according to claim 2, wherein the metal and carbon containing layer is formed on the high-k layer.

5. The method according to claim 1, wherein the metal precursor comprises a rare earth metal.

6. The method according to claim 5, wherein the rare earth metal is selected from scandium (Sc), yttrium (Y), lanthanum (La), and erbium (Er).

7. The method according to claim 1, wherein the metal precursor comprises a transition metal.

8. The method according to claim 7, wherein the transition metal is selected from a list consisting of Ti, Zr, Hf, V, Nb, Ta, Cr, Mo, W, and Mn.

9. The method according to claim 1, wherein the metal precursor comprises a cyclopentadienyl ligand.

10. The method according to claim 1, wherein the metal precursor comprises an amidinate ligand.

11. The method according to claim 1, wherein the metal precursor comprises an alkylsilazido ligand.

12. The method according to claim 1, wherein the metal precursor comprises an dialkylamido ligand.

13. The method according to claim 1, wherein the metal precursor comprises a metal halide.

14. The method according to claim 1, wherein the metal precursor comprises an arene or alkylarene ligand.

15. The method according to claim 1, wherein ones from the plurality of deposition cycles further comprise a nitrogen reactant pulse that comprises introducing a nitrogen reactant to the reaction chamber, thereby contacting the substrate with the nitrogen reactant.

16. The method according to claim 15, wherein the nitrogen reactant is selected from ammonia, hydrazine, and a hydrazine derivative.

17. The method according to claim 15, wherein the nitrogen reactant comprises a hydrazine derivative selected from 1,1-dimethylhydrazine and tert-butylhydrazine.

18. The method according to claim 1, wherein the carbon reactant comprises a cyclodiene.

19. The method according to claim 18, wherein the cyclodiene is selected from 1,3-cyclohexadiene and 1,4-cyclohexadiene.

20. The method according to claim 19, wherein the cyclodiene comprises one or more alkyl or alkylsilyl substituents.
